(19) United States
(12) Patent Application Publication
(10) Pub. No.: US 2011/0134591 A1
(43) Pub. Date: Jun. 9, 2011

(54) ELECTRONIC DEVICE

(75) Inventor: LUNG DAI, Tu-Cheng (TW)

(73) Assignee: HON HAI PRECISION INDUSTRY CO., LTD., Tu-Cheng (TW)

(21) Appl. No.: 12/824,779

(22) Filed: Jun. 28, 2010

(30) Foreign Application Priority Data
Dec. 8, 2009 (CN) 200910311079.9

(51) Int. Cl. H05K 7/00

(52) U.S. Cl. 361/679.01

(57) ABSTRACT

An electronic device comprises a host, a first connector having a first function, a second connector having a second function. The first connector and second connector electrically connect with the host. The first connector comprises several first cables. The second connector comprises several second cables. A first clamp and a second clamp respectively clamp the several first and several second cables together.

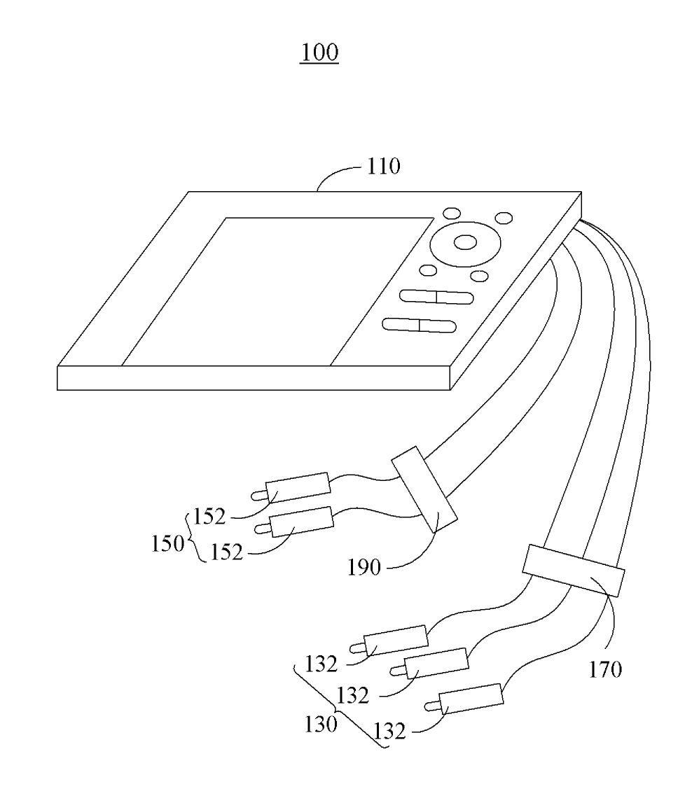

### BACKGROUND

1. Technical Field

The present disclosure relates to electronic devices; and particularly to an electronic device with more than one connector.

2. Description of Related Art

An optical disc player commonly has an audio connector and a video connector for electrically connecting to a display such as a television. The video connector includes three video cables each having a plug, and plugs of the video cables are typically color coded red, green, and blue respectively. The audio connector includes two audio cables each having a plug, and plugs of the audio cables are color coded red and white respectively. The red plug of the video cables and the red plug of the audio cables are the same and can be mistaken for each other by users and inserted into the wrong sockets of the television.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the view.

The FIGURE is a schematic view of an electronic device in accordance with an exemplary embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

Referring to the FIGURE, an electronic device 100 includes a host 110, a first connector 130 having a first function, a second connector 150 having a second function, a first clamp 170, and a second clamp 190. In the embodiment, the electronic device is an optical disc player.

The host 110 electrically connects with the first connector 130, and the second connector 150. The host 110 is capable of electrically connecting with a peripheral device (not shown) via the first connector 130 and the second connector 150. In the embodiment, the peripheral device is a television.

The first connector 130 includes three first cables 132 each having a plug. The three first cables 132 are clamped together by the first clamp 170. In the embodiment, the first connector 130 is used for transmitting video signals, and each first cable 132 is a video cable.

The second connector 150 includes two second cables 152 each having a plug. The two second cables 150 are clamped together by the second clamp 190. In the embodiment, the second connector 150 is used for transmitting audio signals, and each second cable 152 is an audio cable.

In use, the three first cables 132 of the first connector 130 are clamped together by the first clamp 170, and the two second cables 152 of the second connector 150 are clamped together by the second clamp 190. As such, even if one plug of the first cables 132 and one plug of the second cables 152 have the same color, the first cable 132 and the second cables 152 are easily differentiated.

It is to be understood, however, that even though information and advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. An electronic device, comprising:
a host;
a first connector having a first function, the first connector electrically connecting with the host, and comprising a plurality of first cables;
a second connector having a second function, the second connector electrically connecting with the host, and comprising a plurality of second cables; and
a first clamp adapted to clamp the plurality of first cables together.

2. The electronic device according to claim 1, further comprising a second clamp adapted to clamp the plurality of second cables together.

3. The electronic device according to claim 2, wherein the first connector is adapted to transmit video signals, and the second connector is adapted to transmit audio signals.

4. The electronic device according to claim 1, wherein the electronic device is an optical disc player.
